(19) United States
(12) Patent Application Publication
(10) Pub. No.: US 2026/0351828 A1
(43) Pub. Date: Nov. 5, 2026

(54) DIGITAL ISOLATOR, APPLICATION CIRCUIT THEREOF, AND ISOLATED COMMUNICATION METHOD

(71) Applicant: DECO INTEGRATION TECHNOLOGY CO.,LIMITED, Shenzhen (CN)

(72) Inventors: Cheng LI, Shenzhen (CN); Tso Wei LI, Shenzhen (CN)

(73) Assignee: DECO INTEGRATION TECHNOLOGY CO.,LIMITED, Shenzhen (CN)

(21) Appl. No.: 19/716,081

(22) Filed: Jun. 22, 2026

Related U.S. Application Data
(63) Continuation of application No. PCT/CN2024/137032, filed on Dec. 5, 2024.

(30) Foreign Application Priority Data
Dec. 22, 2023 (CN) 202311775419.X

(51) Int. Cl. H01P 1/36; H01H 1/20; H04B 1/44

(52) U.S. Cl. CPC H01P 1/36; H01H 1/20; H04B 1/44; H01H 2001/2091

(57) ABSTRACT

A digital isolator, an application circuit thereof, and an isolated communication method are disclosed. The digital isolator includes a first millimeter-wave circuit and a second millimeter-wave circuit, where the first millimeter-wave circuit includes a first millimeter-wave antenna, a first millimeter-wave transmitter, and a power detector, and the second millimeter-wave circuit includes a second millimeter-wave antenna, a second millimeter-wave receiver, a second millimeter-wave transmitter, and a switch; and the first millimeter-wave transmitter and the power detector are separately connected to the first millimeter-wave antenna, the second millimeter-wave antenna is connected to both the second millimeter-wave transmitter and the second millimeter-wave receiver through the switch, and the switch is further connected to a second isolated circuit corresponding to the second millimeter-wave circuit. The present invention can implement bidirectional communication between two isolated ends only using a single channel formed by a set of millimeter-wave antennas, thereby reducing design complexity and area requirement.

### RELATED APPLICATIONS

The present patent document is a continuation of PCT Application Serial No. PCT/CN2024/137032, filed Dec. 5, 2024, designating the United States and published in English, which is hereby incorporated by reference.

The present patent document claims the benefit of priority to Patent Application No. 202311775419.X, filed Dec. 22, 2023, and entitled “DIGITAL ISOLATOR, APPLICATION CIRCUIT THEREOF, AND ISOLATED COMMUNICATION METHOD,” the entire contents of each of which are incorporated herein by reference.

### BACKGROUND

### 1. Technical Field

The present invention relates to the field of isolated communication technologies, and in particular, to a digital isolator, an application circuit thereof, and an isolated communication method.

### 2. Background Information

Existing digital isolators and application circuits (for example, half-bridge drivers, DC/DC inverters, ADCs, or DACs) thereof need to be equipped with at least two sets of TX-RX and two sets of coupling devices to implement signal back-transmission.

FIG. 1(a) and FIG. 1(b) each is a diagram of a structure of a typical digital isolator used in a half-bridge driver, and FIG. 2 is a diagram of a structure of a novel millimeter-wave isolator used in a half-bridge driver. A working principle of application of the two types of isolators can be summarized as follows: In a routine working state, a circuit in a left low-voltage region transmits a control signal to a circuit in a right high-voltage region, and the circuit in the right high-voltage region detects a voltage or a timing state, and sends a pulse signal back to the circuit in the left low-voltage region upon detecting an abnormality to prompt the abnormality; and the circuit in the left low-voltage region adjusts a signal transmitted to the circuit in the right high-voltage region or cuts off transmission based on the pulse signal. It may be learned that both the conventional typical digital isolator and the novel digital isolator require a two-channel configuration to implement signal back-transmission.

The two-channel configuration of the digital isolator not only requires a large area but also involves complex design issues.

### BRIEF SUMMARY

The present invention is intended to resolve at least one of the technical problems in the foregoing technology to a certain extent. In view of this, an objective of the present invention is to provide a digital isolator, an application circuit thereof, and an isolated communication method, thereby reducing design complexity and an area required for an isolation device while achieving bidirectional communication between two isolated ends.

To achieve the foregoing objective, according to a first aspect, an embodiment of the present invention provides a digital isolator, including a first millimeter-wave circuit and a second millimeter-wave circuit, where the first millimeter-wave circuit includes a first millimeter-wave antenna, a first millimeter-wave transmitter, and a power detector, and the second millimeter-wave circuit includes a second millimeter-wave antenna, a second millimeter-wave receiver, a second millimeter-wave transmitter, and a switch;
the first millimeter-wave transmitter and the power detector are separately connected to the first millimeter-wave antenna, the second millimeter-wave antenna is connected to both the second millimeter-wave transmitter and the second millimeter-wave receiver through the switch, and the switch is further connected to a second isolated circuit corresponding to the second millimeter-wave circuit;
the switch is configured to switch from originally communicating with the second millimeter-wave receiver to communicating with the second millimeter-wave transmitter when the second millimeter-wave circuit sends a second signal to the first millimeter-wave circuit; and
the power detector is configured to detect whether a power transmitted from the first millimeter-wave circuit to the second millimeter-wave circuit decreases due to a near-field pulling effect occurring between the first millimeter-wave antenna and the second millimeter-wave antenna.

According to the digital isolator in this embodiment of the present invention, by utilizing the near-field pulling effect of the millimeter-wave antenna and switching communication of the switch between the receiver and the transmitter, bidirectional communication between two isolated ends can be implemented using only a single channel formed by one set of millimeter-wave antennas. In comparison with a digital isolator in a conventional technology which must be configured with two sets of antennas to form dual channels to implement bidirectional communication, the present invention not only reduces design complexity but also lowers an area requirement.

In addition, the digital isolator provided in the foregoing embodiment of the present invention may further have the following additional technical features:

Optionally, a distance between the first millimeter-wave antenna and the second millimeter-wave antenna ranges from 2 mm to 3 mm (including 2 and 3).

Optionally, the switch includes a switch a and a switch b, the second millimeter-wave antenna is connected to the second millimeter-wave transmitter through the switch a, and the second millimeter-wave antenna is connected to the second millimeter-wave receiver through the switch b;
the switch a is configured to: be turned on when the first millimeter-wave circuit sends a first signal to the second millimeter-wave circuit, and be turned off when the second millimeter-wave circuit sends the second signal to the first millimeter-wave circuit; and
the switch b is configured to: be turned on when the second millimeter-wave circuit sends the second signal to the first millimeter-wave circuit, and be turned off when the first millimeter-wave circuit sends the first signal to the second millimeter-wave circuit.

To achieve the foregoing objective, according to a second aspect, an embodiment of the present invention provides an application circuit of a digital isolator, including the digital isolator, and further including a first isolated circuit and a second isolated circuit, where the first millimeter-wave transmitter and the power detector are separately connected to the first isolated circuit, and the second millimeter-wave receiver and the second millimeter-wave transmitter are separately connected to the second isolated circuit.

According to the application circuit of the digital isolator in this embodiment of the present invention, by utilizing the near-field pulling effect of the millimeter-wave antenna and switching communication of the switch between the receiver and the transmitter, bidirectional communication between the first isolated circuit and the second isolated circuit can be implemented by an isolator using only a single channel formed by one set of millimeter-wave antennas. In comparison with a digital isolator in a conventional technology which must be configured with two sets of antennas to form dual channels to implement bidirectional communication, the present invention not only reduces design complexity but also lowers an area requirement.

In addition, the application circuit of the digital isolator provided in the foregoing embodiment of the present invention may further have the following additional technical features:

Optionally, the first isolated circuit is a low-voltage circuit, and the second isolated circuit is a high-voltage circuit.

Optionally, the first isolated circuit is a low-voltage half-bridge circuit, and the second isolated circuit is a high-voltage half-bridge circuit;
the low-voltage half-bridge circuit includes a low-voltage half-bridge controller, and the high-voltage half-bridge circuit includes a high-voltage half-bridge controller; and
the first millimeter-wave transmitter and the power detector are separately connected to the low-voltage half-bridge controller, and the second millimeter-wave receiver, the second millimeter-wave transmitter, and the switch are separately connected to the high-voltage half-bridge controller.

To achieve the foregoing objective, according to a third aspect, an embodiment of the present invention provides an isolated communication method based on the digital isolator, including:
when the first millimeter-wave circuit sends the first signal to the second millimeter-wave circuit, transmitting, by the first millimeter-wave transmitter of the first millimeter-wave circuit, the first signal to the second millimeter-wave circuit through the first millimeter-wave antenna; and after the second millimeter-wave antenna of the second millimeter-wave circuit receives the first signal, transmitting the first signal to the second millimeter-wave receiver through the switch; and
when the second millimeter-wave circuit sends the second signal to the first millimeter-wave circuit, switching, by the switch, from originally communicating with the second millimeter-wave receiver to communicating with the second millimeter-wave transmitter; transmitting, by the second millimeter-wave transmitter, the second signal to the second millimeter-wave antenna; causing a power transmitted by the first millimeter-wave transmitter to decrease due to the near-field pulling effect between the first millimeter-wave antenna and the second millimeter-wave antenna; and after the power detector of the first millimeter-wave circuit detects that the power transmitted by the first millimeter-wave transmitter decreases, prompting a first isolated circuit corresponding to the first millimeter-wave circuit.

According to the isolated communication method in this embodiment of the present invention, based on the digital isolator implemented by utilizing the near-field pulling effect of the millimeter-wave antenna, bidirectional communication between the first isolated circuit and the second isolated circuit can be implemented using only a single channel formed by one set of millimeter-wave antennas. In comparison with an isolated communication method in a conventional technology which must use two sets of antennas to form dual channels to implement bidirectional communication, the present invention implements bidirectional communication between two isolated ends using a single channel.

In addition, the application circuit of the digital isolator provided in the foregoing embodiment of the present invention may further have the following additional technical features:

Optionally, the first isolated circuit is a low-voltage circuit, and the second isolated circuit is a high-voltage circuit.

Optionally, the first isolated circuit is a low-voltage half-bridge circuit, the second isolated circuit is a high-voltage half-bridge circuit, the low-voltage half-bridge circuit includes a low-voltage half-bridge controller, the high-voltage half-bridge circuit includes a high-voltage half-bridge controller, and the switch is controlled by the high-voltage half-bridge controller.

Optionally, prompting the first isolated circuit corresponding to the first millimeter-wave circuit includes:
informing, by the power detector, the low-voltage half-bridge controller that the high-voltage half-bridge circuit is abnormal; and
controlling, by the low-voltage half-bridge controller, to turn off the first millimeter-wave transmitter or to adjust a transmission power of the first millimeter-wave transmitter.

### BRIEF DESCRIPTION OF THE DRAWINGS

FIG. 1(a) and FIG. 1(b) are diagrams of structures of two typical digital isolators used in half-bridge drivers in a conventional technology;

FIG. 2 is a diagram of a structure of a novel millimeter-wave isolator used in a half-bridge driver in a conventional technology;

FIG. 3 is a diagram 1 of a structure of a digital isolator according to an embodiment of the present invention;

FIG. 4 is a configuration example diagram of a first millimeter-wave antenna and a second millimeter-wave antenna according to an embodiment of the present invention;

FIG. 5 is a diagram of S-parameter curves between a first millimeter-wave antenna and a second millimeter-wave antenna in a configuration example of FIG. 4;

FIG. 6 is a diagram of a curve of a power transmitted by a first millimeter-wave transmitter when a second millimeter-wave antenna serves as a transmit antenna in a configuration example of FIG. 4;

FIG. 7 is a diagram 2 of a structure of a digital isolator according to an embodiment of the present invention; and

FIG. 8 is a diagram of a structure of an application circuit of a digital isolator according to an embodiment of the present invention.

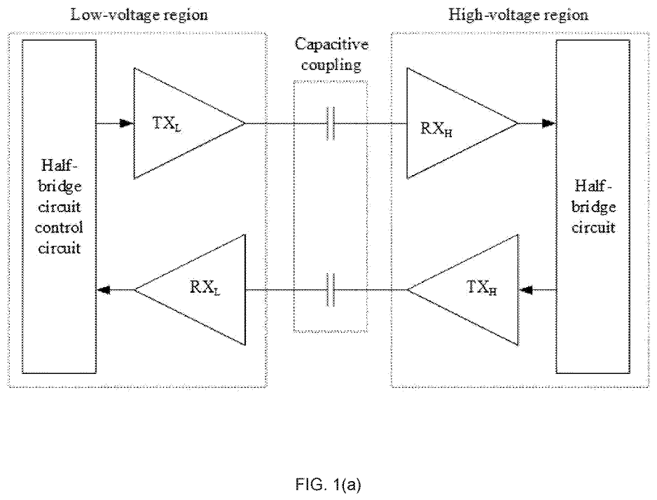

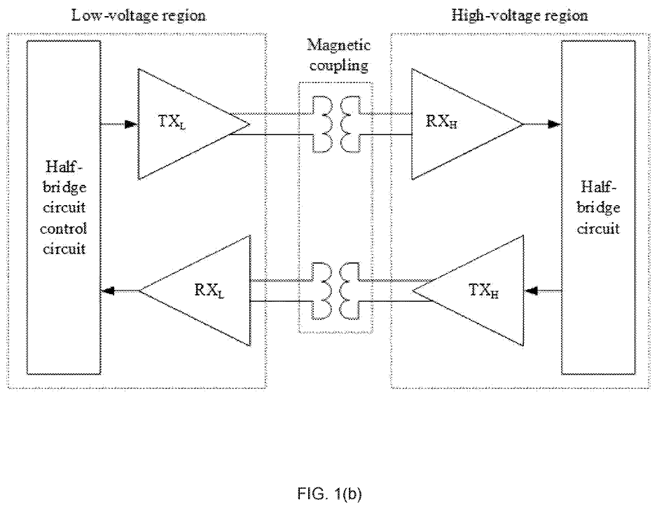

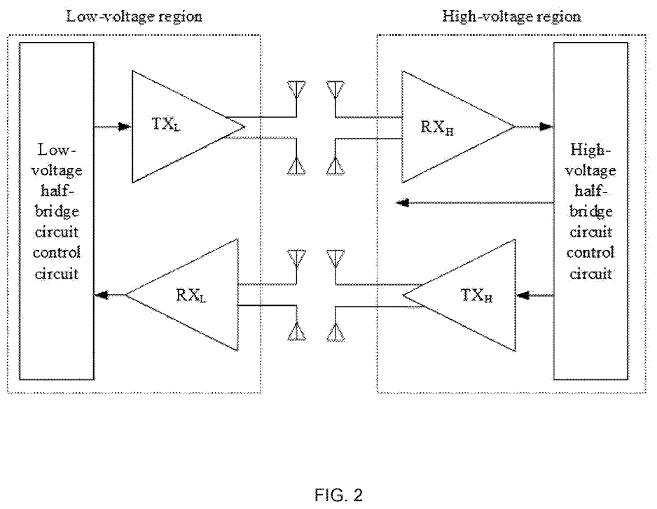

### DETAILED DESCRIPTION OF THE DRAWINGS AND THE PRESENTLY PREFERRED EMBODIMENTS

The following describes embodiments of the present invention in detail. Examples of embodiments are shown in the accompanying drawings. Same or similar reference numerals represent same or similar elements or elements with same or similar functions throughout. The embodiments described below with reference to the accompanying drawings are exemplary and are merely used to explain the present invention, and shall not be construed as a limitation on the present invention.

In the present invention, by utilizing a near-field pulling effect of a millimeter-wave antenna, bidirectional communication between two isolated ends can still be implemented using only a single channel that needs to be configured in an isolator. In comparison with a conventional technology which requires dual channels to implement bidirectional communication, this significantly reduces design complexity and lowers an area requirement of the isolator.

To better understand the foregoing technical solutions, the following describes example embodiments of the present invention in detail with reference to the accompanying drawings. Although example embodiments of the present invention are shown in the accompanying drawings, it should be understood that the present invention may be implemented in various forms and should not be construed as being limited to the embodiments described herein. Conversely, these embodiments are provided to enable a more thorough understanding of the present invention and to fully convey the scope of the present invention to a person skilled in the art.

To better understand the foregoing technical solutions, the following describes the foregoing technical solutions in detail with reference to the accompanying drawings and specific implementations in this specification.

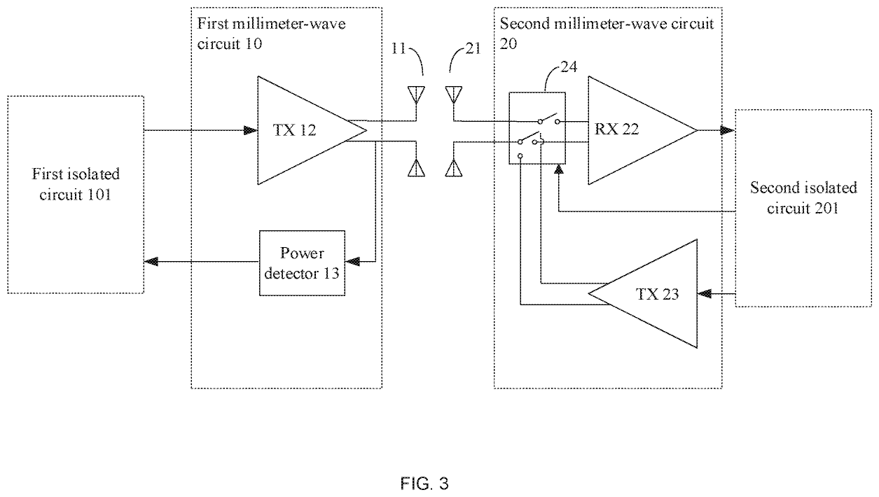

FIG. 3 is a diagram of a structure of a digital isolator according to an embodiment of the present invention. As shown in FIG. 3, this embodiment of the present invention provides the digital isolator, including a first millimeter-wave circuit 10 and a second millimeter-wave circuit 20, where the first millimeter-wave circuit 10 includes a first millimeter-wave antenna 11, a first millimeter-wave transmitter TX 12, and a power detector 13, and the second millimeter-wave circuit 20 includes a second millimeter-wave antenna 21, a second millimeter-wave receiver RX 22, a second millimeter-wave transmitter TX 23, and a switch 24;
the first millimeter-wave transmitter TX 12 and the power detector 13 are separately connected to the first millimeter-wave antenna 11, and further separately connected to a first isolated circuit 101;
the second millimeter-wave antenna 21 is connected to both the second millimeter-wave transmitter TX 23 and the second millimeter-wave receiver RX 22 through the switch 24, and the switch 24 is further connected to a second isolated circuit 201 corresponding to the second millimeter-wave circuit 20;
the switch is configured to switch from originally communicating with the second millimeter-wave receiver to communicating with the second millimeter-wave transmitter when the second millimeter-wave circuit sends a second signal to the first millimeter-wave circuit; and
the power detector is configured to detect whether a power transmitted from the first millimeter-wave circuit to the second millimeter-wave circuit decreases due to a near-field pulling effect occurring between the first millimeter-wave antenna and the second millimeter-wave antenna.

A working principle of the digital isolator described in this embodiment is as follows:

In a normal transmission state, the second isolated circuit corresponding to the second millimeter-wave circuit controls the second millimeter-wave antenna to communicate with the second millimeter-wave receiver through the switch, so that the second millimeter-wave antenna serves as a receive antenna; an input end of the first isolated circuit corresponding to the first millimeter-wave circuit transmits a first signal (pulse modulation signal, for example, Pulse Width Modulation, PWM) to the first millimeter-wave transmitter of the first millimeter-wave circuit; the first millimeter-wave transmitter performs modulation by using a high-frequency carrier for transmission through the first millimeter-wave antenna; and the second millimeter-wave antenna, serving as the receive antenna, receives the first signal transmitted from the first millimeter-wave antenna, and then directs the first signal to the second millimeter-wave receiver that communicates with the second millimeter-wave antenna.

When the second millimeter-wave circuit needs to transmit a signal back to the first millimeter-wave circuit, the second millimeter-wave circuit controls the switch to switch from originally communicating with the second millimeter-wave receiver to communicating with the second millimeter-wave transmitter, so that the first millimeter-wave antenna changes from a receive antenna to a transmit antenna; and a simple pulse signal transmitted by the second millimeter-wave transmitter is transmitted to the second millimeter-wave antenna through the switch for transmission. At this time, the second millimeter-wave antenna and the first millimeter-wave antenna both serve as transmit antennas and both transmit signals, and a distance between the second millimeter-wave antenna and the first millimeter-wave antenna is short. Therefore, a strong inter-antenna near-field pulling effect may occur between the first millimeter-wave antenna and the second millimeter-wave antenna, so that a transmission power of the first millimeter-wave circuit is lower than that in the normal transmission state. After the power detector of the first millimeter-wave circuit detects this change, a prompt may be provided to the first isolated circuit corresponding to the first millimeter-wave circuit, thereby achieving an objective of the second millimeter-wave circuit transmitting the signal back to the first millimeter-wave circuit.

When the second millimeter-wave circuit needs to transmit the signal back to the first millimeter-wave circuit, it is typically because the second isolated circuit is abnormal and returns a signal back-transmission prompt, for example, overheating of the second isolated circuit, loss of a signal received by the second millimeter-wave circuit, abnormality of an output signal of the first millimeter-wave circuit, abnormal operation of a high-voltage device. Corresponding to an application scenario in which the second isolated circuit transmits the signal back to the first isolated circuit for prompting due to the abnormality, after receiving the prompt, the first isolated circuit controls to turn off the first millimeter-wave transmitter or to adjust a transmission power of the first millimeter-wave transmitter.

This embodiment leverages a fact that a configuration requirement for a distance between millimeter-wave antennas differs from a configuration requirement for a distance between other antennas (where the distance between the millimeter-wave antennas typically needs to range from 2 mm to 3 mm (including 2 and 3) while the distance between the other antennas is much larger), which precisely meets a distance requirement for producing a near-field pulling effect between antennas. Therefore, by fully utilizing the antenna near-field pulling effect and switching coordination of the switch, bidirectional communication between two isolated ends can be implemented using a single channel formed by one set of millimeter-wave antennas (for example, the first millimeter-wave antenna and the second millimeter-wave antenna); and arrangement of the first millimeter-wave receiver and a control circuit thereof can be omitted. In other words, according to the digital isolator in this embodiment, arrangement of one set of millimeter-wave antennas, one receiver, and a control circuit thereof can be omitted, thereby reducing design complexity, lowering an area requirement, and offering promising application prospects.

In some specific implementations of this embodiment, the first isolated circuit and the second isolated circuit may be any two circuits that require communication isolation. A most common case is communication isolation between high-voltage and low-voltage circuits. The first isolated circuit is a low-voltage circuit, and the second isolated circuit is a high-voltage circuit. Specifically, this solution may be applied to devices such as half-bridge drivers, DC/DC inverters, ADCs, or DACs for safe and reliable communication isolation between high and low voltages.

With reference to specific experimental data, the following describes in detail application of the inter-antenna near-field pulling effect occurring between the first millimeter-wave antenna and the second millimeter-wave antenna in this embodiment.

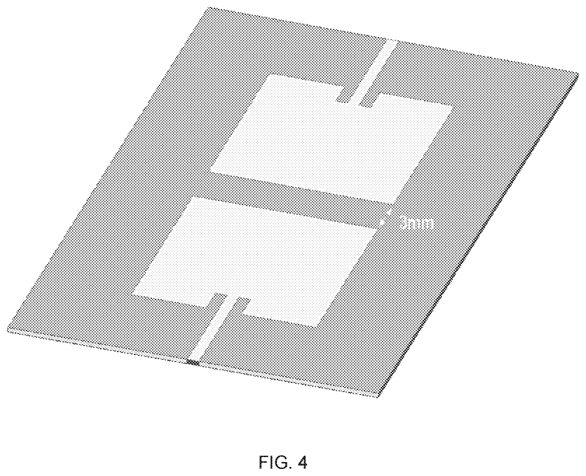

FIG. 4 is a configuration example diagram of the first millimeter-wave antenna and the second millimeter-wave antenna in this embodiment. An example spacing between the first millimeter-wave antenna and the second millimeter-wave antenna in the figure is 3 mm.

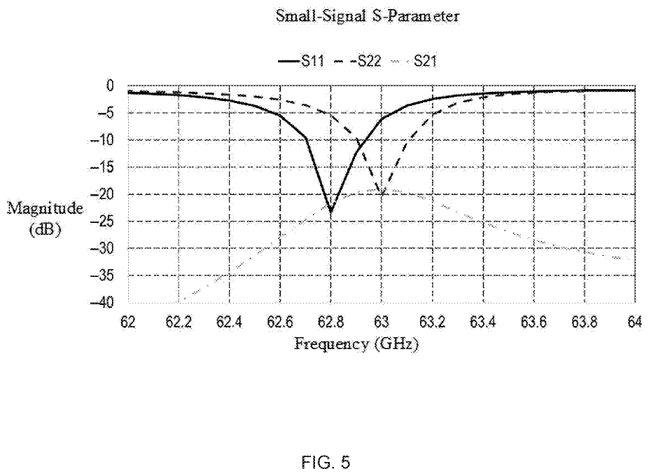

FIG. 5 is a diagram of S-parameter curves between the first millimeter-wave antenna and the second millimeter-wave antenna in a configuration example of FIG. 4. S11 is a reflection coefficient (reflection coefficient) of the first millimeter-wave antenna in a low-voltage region, and S22 is a reflection coefficient of the second millimeter-wave antenna in a high-voltage region when serving as a receive antenna. It may be learned from FIG. 5 that both the first millimeter-wave antenna and the second millimeter-wave antenna have good matching near 62.8 GHz (<−10 dB, for example, more than 90% of energy may be transmitted). S21 in the figure is a transmission coefficient (transmission coefficient) between the first millimeter-wave antenna and the second millimeter-wave antenna when the second millimeter-wave antenna in the high-pressure region serves as a transmit antenna, and is a ratio of energy received by the second millimeter-wave antenna to energy transmitted by the first millimeter-wave antenna. Therefore, a larger S21 indicates more energy received by the second millimeter-wave antenna from the first millimeter-wave antenna, and vice versa. S21 may also be expressed as mutual coupling between the first millimeter-wave antenna and the second millimeter-wave antenna. In other words, a larger S21 indicates stronger coupling between the two antennas, and vice versa. It may be learned from the figure that an antenna array in the configuration example of FIG. 4 has an S21 of approximately −19.6 dB near 62.8 GHz.

It should be particularly noted herein that, for a far-field antenna array (where a distance between antennas in an existing non-millimeter-wave antenna array is large), S21/S12<−40 dB, namely, S21<−40 dB and S12<−40 dB, where S21 and S12 correspond to a same antenna, namely, the second millimeter-wave antenna. Therefore, there is no mutual coupling effect between antenna arrays. However, in this embodiment, the first millimeter-wave antenna and the second millimeter-wave antenna serve as a near-field antenna array, where S21/S12=~−20 dB, namely, S21=~−20 dB and S12=~−20 dB, and therefore there is mutual coupling. In addition, in this embodiment, an antenna array including the first millimeter-wave antenna and the second millimeter-wave antenna typically operates as one transmitter and one receiver (TX and RX). In this case, mutual coupling (namely, the near-field pulling effect) between the near-field antennas has no impact on normal transmission of the antenna array. However, when antennas in the antenna array are all transmit antennas, mutual coupling between the near-field antennas may affect this antenna array. In this embodiment of the present invention, the “coupling between the near-field antennas” is utilized to implement signal back-transmission between the two isolated ends.

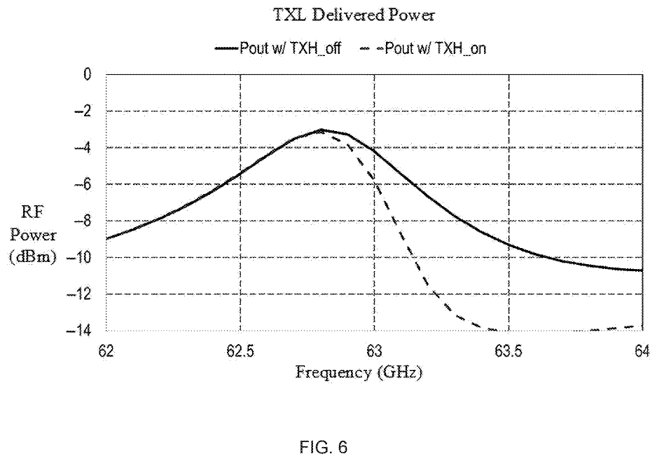

FIG. 6 is a diagram of a curve of a power transmitted by the first millimeter-wave transmitter when the second millimeter-wave antenna serves as a transmit antenna in the configuration example of FIG. 4. It may be learned from FIG. 6 that, in a normal transmission mode, that is, when the second millimeter-wave antenna serves as a receive antenna, the first millimeter-wave transmitter transmits a power of −3 dBm at 62.8 GHz (corresponding to a solid line in the figure); and in a back-transmission mode, that is, when the second millimeter-wave antenna serves as a transmit antenna, the first millimeter-wave transmitter transmits a power of −3.14 dBm at 62.8 GHz (corresponding to a dashed line in the figure). It may be learned that the first millimeter-wave transmitter has a transmission power difference of 0.14 dBm in the two modes; and by detecting this 0.14 dBm difference with the power detector in the low-voltage region, it may be determined whether the high-voltage region is normal (where back-transmission is considered an abnormality).

In addition, it should be noted that a power detector in an existing isolator is configured to detect a specific value of a power transmitted by a transmitter; and in this embodiment of the present invention, the power detector is configured to detect whether a power transmitted by the transmitter decreases, specifically to detect a power difference in the two modes, and determine whether to send prompt information to the control circuit based on the power difference. Therefore, the power detector in this embodiment of the present invention is substantially different in function from the existing power detector.

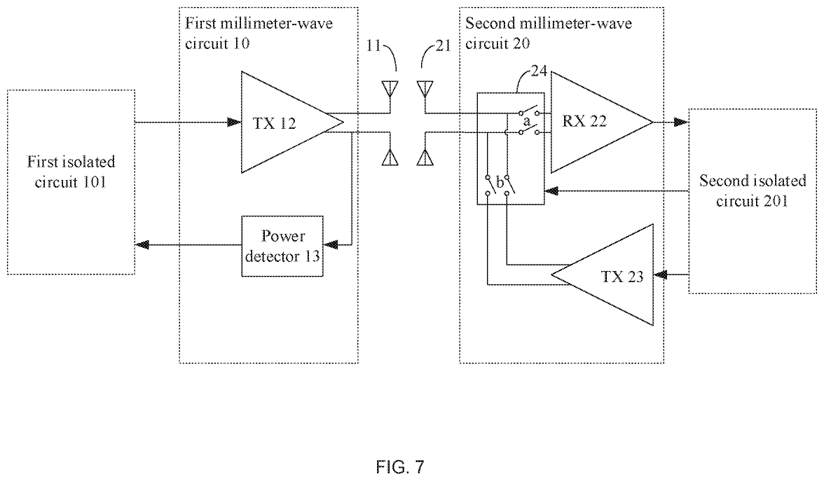

In some specific implementations of this embodiment, as shown in FIG. 7, the switch 24 specifically includes a switch a and a switch b, the second millimeter-wave antenna is connected to the second millimeter-wave transmitter through the switch a, and the second millimeter-wave antenna is connected to the second millimeter-wave receiver through the switch b;
the switch a is configured to: be turned on when the first millimeter-wave circuit sends the first signal to the second millimeter-wave circuit, and be turned off when the second millimeter-wave circuit sends the second signal to the first millimeter-wave circuit; and
the switch b is configured to: be turned on when the second millimeter-wave circuit sends the second signal to the first millimeter-wave circuit, and be turned off when the first millimeter-wave circuit sends the first signal to the second millimeter-wave circuit.

Herein, the switch is embodied as two independent switches, namely, the Switch a and the Switch b, to implement precise control of switching communication between the second millimeter-wave receiver and the second millimeter-wave transmitter.

A working principle of the foregoing specific implementation is as follows:

In a normal transmission state, the second isolated circuit controls the switch a to be turned on and the switch b to be turned off, the first millimeter-wave transmitter of the first millimeter-wave circuit sends the first signal to the second millimeter-wave circuit through the first millimeter-wave antenna, and the second millimeter-wave antenna of the second millimeter-wave circuit receives the first signal and transmits the first signal to the second millimeter-wave receiver.

When the second millimeter-wave circuit needs to transmit a signal back to the first millimeter-wave circuit, the second isolated circuit controls the switch b to be turned on and the switch a to be turned off, and the second millimeter-wave transmitter of the second millimeter-wave circuit transmits the second signal to the second millimeter-wave antenna for transmission. At the same time, the first millimeter-wave antenna still normally transmits the first signal. Therefore, a near-field pulling effect occurs between the first millimeter-wave antenna and the second millimeter-wave antenna, causing a power transmitted by the first millimeter-wave transmitter to decrease; and after the power detector of the first millimeter-wave circuit detects that the power transmitted by the first millimeter-wave transmitter decreases, the first isolated circuit corresponding to the first millimeter-wave circuit is prompted, thereby achieving an objective of the second millimeter-wave circuit transmitting a signal back to the first millimeter-wave circuit.

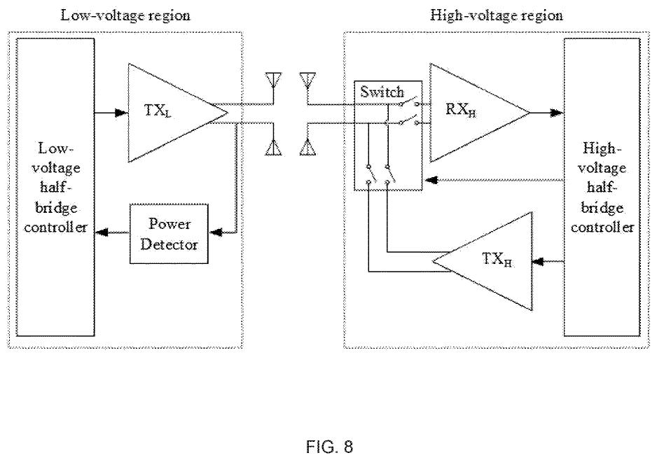

FIG. 8 is a diagram of a structure of an application circuit of a digital isolator according to an embodiment of the present invention. Based on the foregoing embodiments, the embodiment of the present invention further provides the application circuit of the digital isolator, including the digital isolator described in the foregoing embodiments. In addition, the application circuit of the digital isolator further includes a first isolated circuit and a second isolated circuit, where the first millimeter-wave transmitter and the power detector are separately connected to the first isolated circuit, and the second millimeter-wave receiver and the second millimeter-wave transmitter are separately connected to the second isolated circuit.

In this embodiment, dual-end isolated communication between the first isolated circuit and the second isolated circuit can be implemented based on the digital isolator described in the preceding embodiments, and a structure of the digital isolator not only can reduce design complexity but also can save an occupied area, thereby contributing to an overall reduction in design complexity and an area in the application circuit.

In some specific implementations of this embodiment, when the digital isolator described in the preceding embodiments is used in a half-bridge drive design, the first isolated circuit is a low-voltage half-bridge circuit, the second isolated circuit is a high-voltage half-bridge circuit, the low-voltage half-bridge circuit includes a low-voltage half-bridge controller, and the high-voltage half-bridge circuit includes a high-voltage half-bridge controller. As shown in FIG. 8, a millimeter-wave transmitter TXL and the power detector (Power Detector) in a low-voltage region are separately connected to the low-voltage half-bridge controller, and a millimeter-wave receiver RXH, a millimeter-wave transmitter TXH, and the switch (Switch) in a high-voltage region are separately connected to the high-voltage half-bridge controller.

In the half-bridge driver design adopting the millimeter-wave digital isolator provided in the foregoing specific implementations, back-transmission of abnormalities from the high-voltage region can still be implemented in a case in which an isolator only needs to be configured with a single channel and arrangement of a low-voltage-end receiver and a control circuit thereof is omitted. In comparison with an existing half-bridge driver that must be configured with dual channels to implement back-transmission of abnormalities from the high-voltage region, this significantly reduces overall circuit design complexity and lowers an area requirement of the half-bridge driver.

An embodiment of the present invention further provides an isolated communication method based on the digital isolator in the preceding embodiments, including:
when the first millimeter-wave circuit sends the first signal to the second millimeter-wave circuit, transmitting, by the first millimeter-wave transmitter of the first millimeter-wave circuit, the first signal to the second millimeter-wave circuit through the first millimeter-wave antenna; and after the second millimeter-wave antenna of the second millimeter-wave circuit receives the first signal, transmitting the first signal to the second millimeter-wave receiver through the switch; and
when the second millimeter-wave circuit sends the second signal to the first millimeter-wave circuit, switching, by the switch, from originally communicating with the second millimeter-wave receiver to communicating with the second millimeter-wave transmitter; transmitting, by the second millimeter-wave transmitter, the second signal to the second millimeter-wave antenna; causing a power transmitted by the first millimeter-wave transmitter to decrease due to the near-field pulling effect between the first millimeter-wave antenna and the second millimeter-wave antenna; and after the power detector of the first millimeter-wave circuit detects that the power transmitted by the first millimeter-wave transmitter decreases, prompting a first isolated circuit corresponding to the first millimeter-wave circuit.

In this embodiment, the first isolated circuit is typically a low-voltage circuit, and the second isolated circuit is typically a high-voltage circuit.

In some specific implementations of this embodiment, the first isolated circuit is a low-voltage half-bridge circuit, the second isolated circuit is a high-voltage half-bridge circuit, the low-voltage half-bridge circuit includes a low-voltage half-bridge controller, the high-voltage half-bridge circuit includes a high-voltage half-bridge controller, and the switch is controlled by the high-voltage half-bridge controller.

In some specific implementations of this embodiment, prompting the first isolated circuit corresponding to the first millimeter-wave circuit specifically includes:
informing, by the power detector, the low-voltage half-bridge controller that the high-voltage half-bridge circuit is abnormal; and
controlling, by the low-voltage half-bridge controller, to turn off the first millimeter-wave transmitter or to adjust a transmission power of the first millimeter-wave transmitter.

According to the isolated communication method in this embodiment, based on the digital isolator provided in the preceding embodiments, bidirectional communication between the first isolated circuit and the second isolated circuit can be implemented using only a single channel formed by one set of millimeter-wave antennas. In comparison with an isolated communication method in a conventional technology which must use two sets of antennas to form dual channels to implement bidirectional communication, the present invention implements bidirectional communication between two isolated ends using a single channel. A specific structure composition of the digital isolator and a connection relationship thereof are not repeated herein. For details, refer to the descriptions in the preceding embodiments.

A person skilled in the art should understand that embodiments of the present invention may be provided as a method, a system, or a computer program product. Therefore, the present invention may use a form of a hardware-only embodiment, a software-only embodiment, or an embodiment with a combination of software and hardware. In addition, the present invention may use a form of a computer program product that is implemented on one or more computer-usable storage media (including but not limited to a disk memory, a CD-ROM, an optical memory, and the like) that include computer-usable program code.

The present invention is described with reference to the flowcharts and/or block diagrams of the method, the device (system), and the computer program product according to embodiments of the present invention. It should be understood that computer program instructions may be used to implement each process and/or each block in the flowcharts and/or the block diagrams and a combination of a process and/or a block in the flowcharts and/or the block diagrams. The computer program instructions may be provided for a general-purpose computer, a dedicated computer, an embedded processor, or a processor of another programmable data processing device to generate a machine, so that the instructions executed by the computer or the processor of the another programmable data processing device generate an apparatus for implementing a specific function in one or more procedures in the flowcharts and/or in one or more blocks in the block diagrams.

These computer program instructions may alternatively be stored in a computer-readable memory that can instruct a computer or another programmable data processing device to work in a specific manner, so that the instructions stored in the computer-readable memory generate an artifact that includes an instruction apparatus. The instruction apparatus implements a specific function in one or more procedures in the flowcharts and/or in one or more blocks in the block diagrams.

These computer program instructions may alternatively be loaded onto a computer or another programmable data processing device, so that a series of operations and steps are performed on the computer or the another programmable data processing device to generate computer-implemented processing, so that the instructions executed on the computer or the another programmable data processing device provide steps for implementing a specific function in one or more procedures in the flowcharts and/or in one or more blocks in the block diagrams.

It should be noted that, in the claims, any reference sign placed between parentheses shall not be construed as limiting the claims. The word “comprising” does not exclude components or steps not listed in the claims. The word “a” or “one” preceding a component does not exclude a plurality of such components. The present invention may be implemented by hardware including several different components and by an appropriately programmed computer. In the unit claims enumerating several apparatuses, several of these apparatuses may be specifically embodied by using a same hardware item. The use of words “first”, “second”, “third,” and the like does not indicate any order. These words may be interpreted as names.

Although preferred embodiments of the present invention have been described, a person skilled in the art, once aware of basic inventive concepts, may make additional changes and modifications to these embodiments. Therefore, the appended claims are intended to be construed as including the preferred embodiments and all changes and modifications that fall within the scope of the present invention.

It is clear that a person skilled in the art can make various modifications and variations to the present invention without departing from the spirit and scope of the present invention. The present invention is intended to cover these modifications and variations of the present invention provided that they fall within the scope of protection defined by the claims of the present invention and their equivalent technologies.

In the descriptions of the present invention, it should be understood that the terms “first” and “second” are merely intended for a purpose of description, and shall not be understood as an indication or implication of relative importance or implicit indication of a quantity of indicated technical features. Therefore, a feature limited by “first” or “second” may explicitly or implicitly include one or more features. In the descriptions of the present invention, unless otherwise clearly specified, “a plurality of” means two or more.

In the present invention, unless otherwise clearly specified and limited, terms such as “installation”, “connected”, “connection”, and “fastened” should be understood in a broad sense, for example, may be a fixed connection, or may be a detachable connection, or integration; or may be a mechanical connection, or may be an electrical connection; or may be a direct connection, or may be an indirect connection through an intermediate medium, or may be internal communication of two elements or an interaction relationship between two elements. A person of ordinary skill in the art may understand specific meanings of the foregoing terms in the present invention based on a specific case.

In the present invention, unless otherwise clearly specified and limited, when a first feature is “above” or “below” a second feature, the first feature may be in direct contact with the second feature, or the first feature may be in indirect contact with the second feature through an intermediate medium. In addition, that the first feature is “above”, “over”, and “beyond” the second feature may be that the first feature is right above or obliquely above the second feature or merely indicate that the first feature is horizontally higher than the second feature. That the first feature is “below”, “under”, or “beneath” the second feature may be that the first feature is right below or obliquely below the second feature or merely indicate that the first feature is horizontally lower than the second feature.

In the descriptions of this specification, reference terms such as “an embodiment”, “some embodiments”, “example”, “specific example”, or “some examples” mean that specific features, structures, materials, or characteristics described with reference to the embodiments or examples are included in at least one embodiment or example of the present invention. In this specification, example expressions of the foregoing terms should not be construed as necessarily meaning a same embodiment or example. In addition, the described specific features, structures, materials, or characteristics may be combined in a suitable manner in any one or more embodiments or examples. Furthermore, in a case in which there is no contradiction, a person skilled in the art may combine and integrate different embodiments or examples described in this specification and features of the different embodiments or examples.

Although the embodiments of the present invention have been shown and described above, it should be understood that the foregoing embodiments are examples and should not be construed as limiting the present invention. A person of ordinary skill in the art may make changes, modifications, replacements, and variations to the foregoing embodiments within the scope of the present invention.

1. A digital isolator, comprising a first millimeter-wave circuit and a second millimeter-wave circuit, wherein the first millimeter-wave circuit comprises a first millimeter-wave antenna, a first millimeter-wave transmitter, and a power detector, and the second millimeter-wave circuit comprises a second millimeter-wave antenna, a second millimeter-wave receiver, a second millimeter-wave transmitter, and a switch;
the first millimeter-wave transmitter and the power detector are separately connected to the first millimeter-wave antenna, the second millimeter-wave antenna is connected to both the second millimeter-wave transmitter and the second millimeter-wave receiver through the switch, and the switch is further connected to a second isolated circuit corresponding to the second millimeter-wave circuit;
the switch is configured to switch from originally communicating with the second millimeter-wave receiver to communicating with the second millimeter-wave transmitter when the second millimeter-wave circuit sends a second signal to the first millimeter-wave circuit; and
the power detector is configured to detect whether a power transmitted from the first millimeter-wave circuit to the second millimeter-wave circuit decreases due to a near-field pulling effect occurring between the first millimeter-wave antenna and the second millimeter-wave antenna.

2. The digital isolator according to claim 1, wherein a distance between the first millimeter-wave antenna and the second millimeter-wave antenna ranges from 2 mm to 3 mm (comprising 2 and 3).

3. The digital isolator according to claim 1, wherein the switch comprises a switch a and a switch b, the second millimeter-wave antenna is connected to the second millimeter-wave transmitter through the switch a, and the second millimeter-wave antenna is connected to the second millimeter-wave receiver through the switch b;
the switch a is configured to: be turned on when the first millimeter-wave circuit sends a first signal to the second millimeter-wave circuit, and be turned off when the second millimeter-wave circuit sends the second signal to the first millimeter-wave circuit; and
the switch b is configured to: be turned on when the second millimeter-wave circuit sends the second signal to the first millimeter-wave circuit, and be turned off when the first millimeter-wave circuit sends the first signal to the second millimeter-wave circuit.

4. An application circuit of a digital isolator, comprising the digital isolator according to claim 1, and further comprising a first isolated circuit and a second isolated circuit, wherein the first millimeter-wave transmitter and the power detector are separately connected to the first isolated circuit, and the second millimeter-wave receiver and the second millimeter-wave transmitter are separately connected to the second isolated circuit.

5. The application circuit of the digital isolator according to claim 4, wherein a distance between the first millimeter-wave antenna and the second millimeter-wave antenna ranges from 2 mm to 3 mm (comprising 2 and 3).

6. The application circuit of the digital isolator according to claim 4, wherein the switch comprises a switch a and a switch b, the second millimeter-wave antenna is connected to the second millimeter-wave transmitter through the switch a, and the second millimeter-wave antenna is connected to the second millimeter-wave receiver through the switch b;
the switch a is configured to: be turned on when the first millimeter-wave circuit sends a first signal to the second millimeter-wave circuit, and be turned off when the second millimeter-wave circuit sends the second signal to the first millimeter-wave circuit; and
the switch b is configured to: be turned on when the second millimeter-wave circuit sends the second signal to the first millimeter-wave circuit, and be turned off when the first millimeter-wave circuit sends the first signal to the second millimeter-wave circuit.

7. The application circuit of the digital isolator according to claim 4, wherein the first isolated circuit is a low-voltage circuit, and the second isolated circuit is a high-voltage circuit.

8. The application circuit of the digital isolator according to claim 4, wherein the first isolated circuit is a low-voltage half-bridge circuit, and the second isolated circuit is a high-voltage half-bridge circuit;
the low-voltage half-bridge circuit comprises a low-voltage half-bridge controller, and the high-voltage half-bridge circuit comprises a high-voltage half-bridge controller; and
the first millimeter-wave transmitter and the power detector are separately connected to the low-voltage half-bridge controller, and the second millimeter-wave receiver, the second millimeter-wave transmitter, and the switch are separately connected to the high-voltage half-bridge controller.

9. An isolated communication method, based on the digital isolator according to claim 1, comprising:
when the first millimeter-wave circuit sends the first signal to the second millimeter-wave circuit, transmitting, by the first millimeter-wave transmitter of the first millimeter-wave circuit, the first signal to the second millimeter-wave circuit through the first millimeter-wave antenna; and after the second millimeter-wave antenna of the second millimeter-wave circuit receives the first signal, transmitting the first signal to the second millimeter-wave receiver through the switch; and
when the second millimeter-wave circuit sends the second signal to the first millimeter-wave circuit, switching, by the switch, from originally communicating with the second millimeter-wave receiver to communicating with the second millimeter-wave transmitter; transmitting, by the second millimeter-wave transmitter, the second signal to the second millimeter-wave antenna; causing a power transmitted by the first millimeter-wave transmitter to decrease due to the near-field pulling effect between the first millimeter-wave antenna and the second millimeter-wave antenna; and after the power detector of the first millimeter-wave circuit detects that the power transmitted by the first millimeter-wave transmitter decreases, prompting a first isolated circuit corresponding to the first millimeter-wave circuit.

10. The isolated communication method according to claim 9, wherein a distance between the first millimeter-wave antenna and the second millimeter-wave antenna ranges from 2 mm to 3 mm (comprising 2 and 3).

11. The isolated communication method according to claim 9, wherein the switch comprises a switch a and a switch b, the second millimeter-wave antenna is connected to the second millimeter-wave transmitter through the switch a, and the second millimeter-wave antenna is connected to the second millimeter-wave receiver through the switch b;
the switch a is configured to: be turned on when the first millimeter-wave circuit sends a first signal to the second millimeter-wave circuit, and be turned off when the second millimeter-wave circuit sends the second signal to the first millimeter-wave circuit; and
the switch b is configured to: be turned on when the second millimeter-wave circuit sends the second signal to the first millimeter-wave circuit, and be turned off when the first millimeter-wave circuit sends the first signal to the second millimeter-wave circuit.

12. The isolated communication method according to claim 9, wherein the first isolated circuit is a low-voltage circuit, and the second isolated circuit is a high-voltage circuit.

13. The isolated communication method according to claim 9, wherein the first isolated circuit is a low-voltage half-bridge circuit, the second isolated circuit is a high-voltage half-bridge circuit, the low-voltage half-bridge circuit comprises a low-voltage half-bridge controller, the high-voltage half-bridge circuit comprises a high-voltage half-bridge controller, and the switch is controlled by the high-voltage half-bridge controller.

14. The isolated communication method according to claim 13, prompting the first isolated circuit corresponding to the first millimeter-wave circuit comprises:
informing, by the power detector, the low-voltage half-bridge controller that the high-voltage half-bridge circuit is abnormal; and
controlling, by the low-voltage half-bridge controller, to turn off the first millimeter-wave transmitter or to adjust a transmission power of the first millimeter-wave transmitter.
